(19) United States
(12) Patent Application Publication
(10) Pub. No.: US 2006/0049430 A1
(43) Pub. Date: Mar. 9, 2006

(54) Field-effect transistor, complementary field-effect transistor, and method of manufacturing field-effect transistor

(75) Inventors: Naoki Kasai, Kanagawa (JP); Yasushi Nakahara, Kanagawa (JP); Hiroshi Kimura, Kanagawa (JP); Toshinori Fukai, Tokyo (JP)

Correspondence Address: YOUNG & THOMPSON, 745 SOUTH 23RD STREET, 2ND FLOOR, ARLINGTON, VA, 22202, US

(73) Assignees: NEC ELECTRONICS CORPORATION, KANAGAWA (JP); NEC CORPORATION, TOKYO (JP)

(21) Appl. No.: 11/207,758

(22) Filed: Aug. 22, 2005

(30) Foreign Application Priority Data
Aug. 20, 2004 (JP) 2004-240752

(51) Int. Cl. H01L 29/76; H01L 29/745

(52) U.S. Cl. 257/213

(57) ABSTRACT

An objective of this invention is to improve an ON-state current of a field-effect transistor.

For this purpose, on a single-crystal silicon substrate 101 having a {100} plane as a principal surface are formed a gate electrode 107 extending substantially in a <010> crystal axis direction of the single-crystal silicon or an axis direction equivalent to the <010> crystal axis direction, and in both sides of the gate electrode 107, source/drain regions 129 on the surface of the single-crystal silicon substrate 101. On the surface of the single-crystal silicon substrate 101 in a region directly below the gate electrode 107 are formed a principal surface and an inclined surface 133 oblique to the principal surface along the extension direction of the gate electrode 107.

This application is based on Japanese patent application NO. 2004-240752, the content of which is incorporated hereinto by reference.

### BACKGROUND OF THE INVENTION

1. Field of the Invention

This invention relates to a field-effect transistor, a complementary field-effect transistor, and a method of manufacturing the field-effect transistor.

2. Description of the Related Art

As the prior art, Japanese Patent Laid-open No. 2004-87640 has disclosed a technique for improving an operation speed of a transistor formed on a single-crystal silicon substrate having a (100) crystal plane as a principal surface. The publication has described that a channel direction of a field-effect transistor can be a <100> axis direction of silicon, allowing the transistor to be operated at a higher speed than that with a conventional <110> axis direction. It has also described that a stress controlling film can be formed on a field-effect transistor to improve drain current properties.

There has been need for reducing a minimum processing dimension required for a gate as need for size reduction of a device has been increased in a field-effect transistor. Thus, improving an ON-state current has been also need in an transistor. There is, therefore, still room for improving an ON-state in a semiconductor device having a configuration as described in Japanese Patent Laid-open No. 2004-87640.

### SUMMARY OF THE INVENTION

We have studied the configuration described in the above publication, and has focused attention to that in the configuration described in the above publication, an upper surface of a channel region is parallel to a principal surface of a silicon substrate. We have considered that since an ON-state current per a unit channel width is constant, that is, unchanged, it is difficult to improve an ON-state current as a channel width is reduced. Furthermore, focusing attention to a channel width and a channel mobility per a unit channel width as new factors contributing to change in an ON-state current in a field-effect transistor, we have conducted intense investigation and finally achieved this invention.

The term, a “channel length” as used in this specification refers to a length of a channel region in a direction connecting source-drain regions. The term, a“channel width” refers to a length of a channel region in a direction perpendicular to the direction connecting source-drain regions, in other words, an extension direction of a gate electrode. The term, a “channel region” refers to a region directly below a gate electrode which separates source/drain regions formed on a substrate.

According to the present invention, there is provided a field-effect transistor comprising a substrate made of single-crystal silicon having a {100} plane as a principal surface; a gate electrode on the substrate, which extends substantially in a direction of the <010> crystal axis of the single-crystal silicon or of an axis equivalent to the <010> crystal axis direction; and source/drain regions on the surface of the substrate in both sides of the gate electrode, wherein the surface of the substrate directly below the gate electrode has the principal surface and an inclined surface oblique to the principal surface along an extension direction of the gate electrode.

A crystal plane represents the three-dimensional position thereof and generally corresponds to three vertical directions of x-axis, y-axis and z-axis. The (001) plane, the (010) plane, the (100) plane, the (00-1) plane, the (0-10) plane and the (−100) plane correspond to each surface of a cube. These planes have similar properties, so they are called as the {001} plane as a whole.

According to the present invention, there is provided a substrate made of single-crystal silicon having a {100} plane as a principal surface; the element isolation region on the substrate; an element region on the substrate which is defined by the element isolation region; a gate electrode on the substrate which extends from the element region to the element isolation region such that it divides the element region and extends substantially in a direction of the <010> crystal axis of the single-crystal silicon or of an axis equivalent to the <010> crystal axis direction; and source/drain regions on the surface of the substrate in both sides divided by the gate electrode, wherein the surface of the substrate directly below the gate electrode has the principal surface and an inclined surface oblique to the principal surface along an extension direction of the gate electrode.

In the present invention, a gate electrode in a substrate made of single-crystal silicon having a {100} plane as a principal surface extends substantially in a <010> crystal axis direction or an axis direction equivalent to the <010> crystal axis direction, and a region directly below the gate electrode in the substrate has an inclined surface oblique to the principal surface along the extension direction of the gate electrode. Thus, a channel region can be formed in a crystal plane in single-crystal silicon with higher channel mobility. By forming an inclined surface, a channel width can be increased in comparison with the case where a substrate surface in a region directly below a gate electrode is substantially a principal surface. Thus, this invention can increase an ON-state current in a field-effect transistor.

Here, in this specification, single crystal silicon having a {100} plane as a principal surface may be inclined from the {100} plane within a given offset angle. As used in this specification, the phrase, “substantially extending in a given crystal-axis direction” allows a deviation within ±5° from the crystal-axis direction. As used in this specification, the phrase, “having a substantially given surface orientation” allows a deviation within ±5° from the surface orientation.

In a field-effect transistor of the present invention, the inclined surface may be formed near the element isolation region. Thus, an ON-state current in the field-effect transistor can be reliably increased.

In a field-effect transistor of the present invention, the inclined surface may be formed by one crystal plane of the above single-crystal silicon. Thus, a crystal plane with higher channel mobility can be selectively used as an inclined surface, and a configuration with a predetermined ON-state current can be provided with good reproductivity.

In a field-effect transistor of the present invention, the inclined surface may be comprised of a plurality of crystal planes of the above single-crystal silicon. Such a configuration can prevent electric field concentration to a given region in a substrate surface and allow a plane with higher channel mobility to be used as an inclined surface.

In a field-effect transistor of the present invention, the inclined surface may comprise a (301) plane of the single-crystal silicon, a plane equivalent to the (301) plane, or a plane oblique to the (301) plane or to the plane equivalent to the (301) plane within 5°. Thus, channel mobility may be reliably increased and a channel width can be adequately increased, resulting in further reliable increase of an ON-state current.

In a field-effect transistor of the present invention, the inclined surface may be curved such that along the <010> crystal axis direction of the single-crystal silicon or the axis direction equivalent to the <010> crystal axis direction, a surface orientation of the inclined surface continuously varies from the <100> crystal axis direction of the single-crystal silicon to an <ab0> crystal axis direction where “a” and “b” are independently an integer or to a direction equivalent to the <ab0> crystal axis direction. Thus, electric field concentration on a substrate surface can be further inhibited.

In a field-effect transistor of the present invention, an area of the inclined surface may be 10% or more of an area of the region separating the source/drain regions in the substrate seen from the normal line of the principal surface. Thus, an inclined surface with higher channel mobility to the principal surface can be adequately ensured, resulting in further increase of an ON-state current.

According to the present invention, there is provided a complementary field-effect transistor comprising an N channel field-effect transistor and a P channel field-effect transistor, wherein the N channel field-effect transistor and the P channel field-effect transistor are any of the field-effect transistors as described above.

In this invention, a P channel type field-effect transistor has an inclined surface, and therefore, channel mobility in the P channel type field-effect transistor can be adequately increased. Since both N channel field-effect transistor and P channel field-effect transistors have an inclined surface, ON-state current properties can be improved while simplifying a manufacturing process.

In a complementary field-effect transistor of the present invention, in the P channel field-effect transistor, an area of the inclined surface can be 10% or more of an area of a region separating the source/drain regions in the substrate seen from the normal line of the principal surface, while in the N channel field-effect transistor, an area of the inclined surface is less than 10% of an area of the region separating the source/drain regions in the substrate seen from the normal line direction of the principal surface. Thus, an ON-state current in the P channel type field-effect transistor can be increased while preventing reduction of an ON-state current in the N channel type field-effect transistor.

A complementary field-effect transistor of the present invention may further comprise a plurality of the P channel field-effect transistors divided by an element isolation region and the single N channel field-effect transistor. Thus, an ON-state current in the P channel type field-effect transistor can be increased while preventing reduction of an ON-state current in the N channel type field-effect transistor.

According to the present invention, there is provided a method of manufacturing a field-effect transistor comprising depositing a mask on a principal surface of a substrate made of single-crystal silicon having a {100} plane as the principal surface; sequentially removing the mask and the substrate to form a concave while forming an element forming region beside the concave; shrinking the sidewall of the mask deposited in the depositing from the concave toward the element forming region to expose a part of the principal surface from the mask; after the exposing the part of the principal surface from the mask, oxidizing the whole surface of the substrate to form an inclined surface oblique to the principal surface in a <010> crystal axis direction or an axis direction substantially equivalent to the <010> crystal axis direction in the substrate exposed from the mask; filling the concave with an insulating film to form an element isolation region; and removing the mask to form a gate electrode extending substantially in the <010> crystal axis direction of the single-crystal silicon or in the axis direction substantially equivalent to the <010> crystal axis direction on the substrate in the element forming region comprising the inclined surface.

In the manufacturing method of the present invention, the mask can be shrunk from the concave toward the element forming region to expose a part of the principal surface from the mask and then the exposed principal surface can be oxidized to form an inclined surface oblique in a <010> crystal axis direction or a direction of an axis substantially equivalent to the <010> crystal axis in the substrate. Thus, a transistor with higher channel mobility and an increased channel width can be reliably manufactured.

Any combination of the above configurations and converted expression of this invention, for example, between a process and an apparatus may be also effective as aspects of this invention.

For example, in the present invention, the field-effect transistor may be a P channel type field-effect transistor to more reliably increase an ON-state current.

In the present invention, the normal line of the inclined surface may be substantially perpendicular to the <010> crystal axis direction of the single-crystal silicon or an axis direction equivalent to the <010> crystal axis direction. Thus, a channel width can be increased and channel mobility can be reliably increased.

In the present invention, the normal line direction of the inclined surface may be an <ab0> axis direction of the single-crystal silicon or an axis direction equivalent to the <ab0> crystal axis direction. Here, “a” and “b” are integers, which may be equal or different. Thus, channel mobility can be further reliably increased. For example, when a principal surface of a substrate is a (100) plane of single-crystal silicon, the normal line of the inclined surface may be in an <ab0> crystal axis direction of the single-crystal silicon.

In the present invention, the gate electrode may protrude in the direction of the principal surface. Thus, an inclined surface may be formed in a region directly below near each of the ends in the gate electrode in its extension direction, resulting in reliable increase of channel mobility.

For example, in the method of manufacturing a semiconductor device according the present invention, the mask may be an SiN film. Thus, an inclined surface can be reliably formed in an element forming region.

In the method of manufacturing a semiconductor device according to the present invention, a shape of the element forming region in a plan view may be substantially a rectangle having a side extending substantially in a direction of a <010> crystal axis of silicon.

In the method of manufacturing a semiconductor device according to the present invention, the sidewall of the mask may be shrunk in a <010> crystal axis direction of the single-crystal silicon or an axis direction equivalent to the <010> crystal axis direction. Thus, an inclined surface with high channel mobility can be reliably formed.

According to the present invention, a technique for improving an ON-state current in a field-effect transistor can be achieved by a configuration that a substrate surface in a region directly below a gate electrode substantially extending in a <010> crystal axis direction of single-crystal silicon comprises a principal surface and an inclined surface oblique to the principal surface along the extension direction of the gate electrode.

Channel mobility of a field-effect transistor (MOSFET) is known to be changed by the crystal plane orientation of Si (for example, T. Sato, Physical Review B, vol. 4, NO. 6, pp. 1950-1960 and 1971). Since the effective mass of a career (an electron or a hole) varies in the crystal plane orientation of Si, the channel mobility of MOSFET changes. The channel mobility of the hole (the career of the P channel field-effect transistor) is the smallest at the {001} plane, and it is increased with the inclination therefrom. Therefore, in the P channel field-effect transistor, according to the change of plane orientation of the inclined plane from <010> crystal axis direction to the <ab0> crystal axis direction (wherein “a” and “b” are independently an integer) or to a direction equivalent to the <ab0> crystal axis, the channel mobility can securely be increased.

On the other hand, the channel mobility of the electron (the career of the N channel field-effect transistor) is the greatest at the {001} plane, and it is reduced with the inclination therefrom. Therefore, in the N channel field-effect transistor, in contrary to the case of P channel field-effect transistor, according to the change of the plane orientation of the inclined plane from <010> crystal axis direction to the <ab0> crystal axis direction (wherein “a” and “b” are independently an integer) or to a direction equivalent to the <ab0> crystal axis, the channel mobility is reduced, while effective channel width is increased by the inclined plane, thus the deterioration of the ON-state current can be suppressed.

Also, independently of the channel mobility, the forming of the inclined plane increases the effective channel width, so the ON-state current property improves both in the P channel field-effect transistor and in the N channel field-effect transistor. FIGS. 12 to 14 show the calculation result about the relation between an inclination angle θ of the inclined plane and the ON-state current.

In the P channel field-effect transistor, as shown in FIGS. 12A, 13A and 14A, the more the inclination angle θ is, that is, the more the plane orientation of the inclined plane is sloped from the {001} plane towards the {011} plane, the more the mobility is. Therefore, the ON-state current of the P channel field-effect transistor is increased by the double effects, one is the effect of the increase of the channel mobility given by the inclined plane, and another is the effect of the increase of the channel width.

On the other hand, in the N channel field-effect transistor, as shown in FIGS. 12B, 13B and 14B, the more the inclination angle θ is, that is, the more the plane orientation of the inclined plane is sloped from the {001} plane towards the {011} plane, the less the mobility is. Therefore, the ON-state current of the N channel field-effect transistor depends on the trade-off between the effect of the decrease of the channel mobility given by the inclined plane and the effect of the increase of the channel width.

In other words, the ON-state current in the N channel field-effect transistor and the P channel field-effect shows different behavior varied by two parameters of the inclination angle and the ratio of the length of the inclined plane/flat plane. In the N channel field-effect transistor, the mobility decreasing is more effective, so when the inclination angle is set large, the tendency of the mobility reduction is towards great. Therefore, as for the N channel field-effect transistor, when the selection of the inclination angle is mistaken, ON-state current may be deteriorated. According to the present invention, as for the N channel field-effect transistor the deterioration of ON-state current can also be suppressed.

### BRIEF DESCRIPTION OF THE DRAWINGS

The above and other objects, advantages and features of the present invention will be more apparent from the following description taken in conjunction with the accompanying drawings, in which:

FIG. 1 is a plan view schematically showing a configuration of an MOS type transistor according to an embodiment.

FIG. 2 is a cross-sectional view taken on line A-A′ of FIG. 1.

FIG. 3 is a perspective view schematically showing a configuration of an MOS type transistor according to an embodiment.

FIG. 4 shows a relationship between an inclination angle θ and a surface orientation in an MOS type transistor according to an embodiment.

FIGS. 5A to 5D are cross-sectional views schematically showing a manufacturing process for an MOS type transistor according to an embodiment.

FIGS. 6A to 6C are cross-sectional view schematically showing a manufacturing process for an MOS type transistor according to an embodiment.

FIG. 7 is a cross-sectional view schematically showing a configuration of an MOS type transistor according to an embodiment.

FIG. 8 is a cross-sectional view schematically showing a configuration of an MOS type transistor according to an embodiment.

FIGS. 9A to 9C are plan views schematically showing a configuration of a CMOS device according to an embodiment.

FIGS. 10A and 10B are plan views schematically showing a configuration of a CMOS device according to an embodiment.

FIG. 11 is a cross-sectional view schematically showing a configuration of an MOS type transistor according to an example.

FIGS. 12A and 12B show a relationship between a WG and an Ion in an MOS type transistor according to an example.

FIGS. 13A and 13B show a relationship between a WG and an Ion in an MOS type transistor according to an example.

FIGS. 14A and 14B show a relationship between a WG and an Ion in an MOS type transistor according to an example.

FIGS. 15A and 15B show a relationship between a WG and an Ion in an MOS type transistor according to an example.

### DETAILED DESCRIPTION OF THE INVENTION

The invention will be now described herein with reference to illustrative embodiments. Those skilled in the art will recognize that many alternative embodiments can be accomplished using the teachings of the present invention and that the invention is not limited to the embodiments illustrated for explanatory purpose. In all the drawings, equivalent elements have the same symbol, whose description is omitted as appropriate.

### Embodiment 1

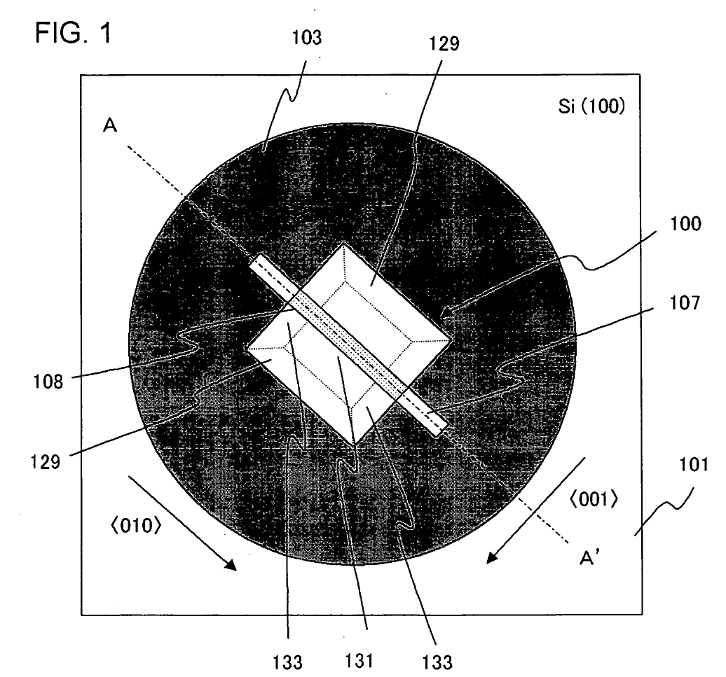

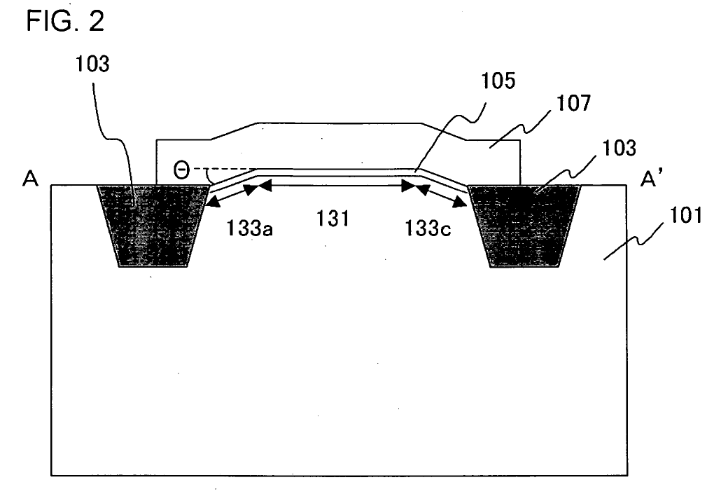

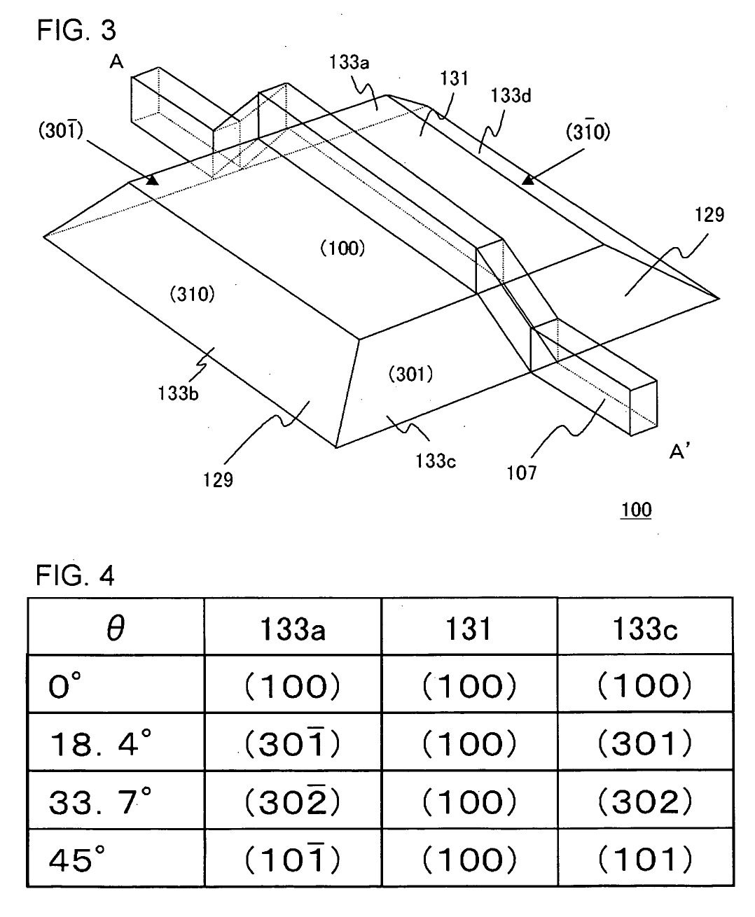

This embodiment relates to a P channel type MOSFET. FIG. 1 is a plan view showing a configuration of an MOS type transistor (P channel type MOSFET) according to this embodiment. FIG. 2 is a cross-sectional view taken on line A-A′ of FIG. 1. FIG. 3 is a perspective view schematically showing a configuration near a gate electrode 107 in an MOS field-effect transistor 100.

The MOS field-effect transistor 100 shown in FIGS. 1 and 2 is formed on a single-crystal silicon substrate 101 having a {100} plane as a principal surface. This invention will be described in connection to an exemplary transistor where the principal surface in the single-crystal silicon substrate 101 is a (100) plane.

There is formed an element isolation region 103 surrounding the lateral sides of the MOS field-effect transistor 100. The element isolation region 103 is buried in the single-crystal silicon substrate 101. In a plan view, an element forming region surrounded by the element isolation region 103 is rectangle. Extension directions of two adjacent sides in the rectangle are a <010> axis direction and a <001> axis direction, respectively.

The MOS field-effect transistor 100 comprises the single-crystal silicon substrate 101; a gate electrode 107 on the single-crystal silicon substrate 101 substantially extending in the <010> crystal axis direction of the single-crystal silicon or an axis direction equivalent to the <010> crystal axis direction; and source/drain regions 129 formed on the single-crystal silicon substrate 101 in both sides of the gate electrode 107.

The MOS field-effect transistor 100 further comprises a gate insulating film 105 formed between the gate electrode 107 and the single-crystal silicon substrate 101. The gate insulating film 105 has a substantially constant thickness without a region where a film thickness is deliberately changed. In FIGS. 1 and 3, the gate insulating film 105 formed between the single-crystal silicon substrate 101 and the gate electrode 107 is not presented.

The gate electrode 107 extends in the <010> axis direction of the silicon. In a plan view, the gate electrode 107 has a shape of rectangle, whose longer side extends in the <010> axis direction. Furthermore, there is formed a channel region 108 in the single-crystal silicon substrate 101 directly below the gate electrode 107. In this embodiment, the channel region 108 has N conductivity type. In both sides of the gate electrode 107, there are formed source/drain regions 129 with P conductivity type near the surface of the single-crystal silicon substrate 101.

In FIG. 1, a width of the channel region is a length of the channel region 108 in the direction of line A-A′. A channel length is a length of the channel region 108 in a direction perpendicular to line A-A′.

As shown in FIGS. 1 to 3, the channel region 108 has a shape of rectangle in a plan view. In the rectangle, extension directions of two adjacent sides are the <010> axis direction and the <001> axis direction of silicon, respectively. As shown in FIG. 2, the channel region 108 has a configuration where the center of the single-crystal silicon substrate 101 extends from the end of the element isolation region 103 to the outside of the single-crystal silicon substrate 101 (the upper direction in FIG. 2) in a direction perpendicular to the principal surface in the single-crystal silicon substrate 101. Furthermore, the channel region 108 comprises an upper surface 131 and an inclined surface 133. The inclined surface 133 is formed near both ends of the gate electrode 107.

In a plan view, the upper surface 131 is in the center of the channel region 108 and parallel to the principal surface of the single-crystal silicon substrate 101, and its plane indices are substantially (100). In this and other embodiments, plane indices of substantially (100) may include a plane oblique to the (100) plane of the single-crystal silicon by a given offset angle.

The inclined surface 133 is formed from the end of the element isolation region 103 to the periphery of the single-crystal silicon substrate 101. The inclined surface 133 comprises an inclined surface 133a and an inclined surface 133c which face to each other via the upper surface 131 along the channel width direction. The single-crystal silicon substrate 101 comprises an inclined surface 133b and an inclined surface 133d which face to each other via the upper surface 131 along the channel length direction in the source/drain region 129. Each of the inclined surfaces 133a to 133d is a single plane and has an equal inclination angle θ to the (100) plane.

The inclination angle θ to the principal surface in the single-crystal silicon substrate 101 is, for example, 10° or more. FIG. 4 shows a relationship between an inclination angle θ and typical plane indices of the inclined surface 133. FIG. 4 shows the plane indices of the inclined surfaces 133a and 133c which face to each other via the upper surface 131. An inclination angle θ to the principal surface in the single-crystal silicon substrate 101 is preferably 20° or more. Thus, an area of the inclined surface 133 in the channel region 108 can be adequately increased in relation to an area of the region separating the source/drain regions 129 in the single-crystal silicon substrate 101 seen from the normal line of the principal surface, and among crystal planes in the silicon single crystal, a plane with higher channel mobility may be used as the inclined surface 133.

In FIG. 3, each of the inclined surfaces 133 has plane indices of {301} and is the (301) plane in the single-crystal silicon or a plane equivalent to the (301) surface. Angles formed by any of the inclined surfaces 133a to 133d with the principal surface in the single-crystal silicon substrate 101 and with the upper surface 131 are equal and about 20°, more specifically 18.4°. Thus, it is the (301) plane of the single-crystal silicon or a plane equivalent to the (301) plane, so that channel mobility can be reliably increased and manufacturing stability can be improved.

Specifically, the inclined surface 133a is a plane inclined from the (100) plane toward the (10-1) plane along the <010> axis direction of silicon, and is the (30-1) plane in this case. The inclined surface 133b is a plane inclined from the (100) plane toward the (110) plane along the <010> axis direction of silicon, and is the (310) plane in this case. The inclined surface 133c is a plane inclined from the (100) plane toward the (101) plane along the <010> axis direction of silicon, and is the (301) plane in this case. The inclined surface 133d is a plane inclined from the (100) plane toward the (1-10) plane along the <010> axis direction of silicon, and is the (3-10) plane in this case.

In the MOS field-effect transistor 100, an area of the inclined surface 133 is 10% or more, preferably 20% or more of an area of the channel region 108 separating the source/drain regions 129 in the single-crystal silicon substrate 101 seen from the normal line direction of the principal surface. Thus, a length of the channel region 108 can be reliably increase in relation to a width of a region for forming the channel region 108. Therefore, in the case of size reduction of a device, a channel width can be adequately ensured while improving channel mobility.

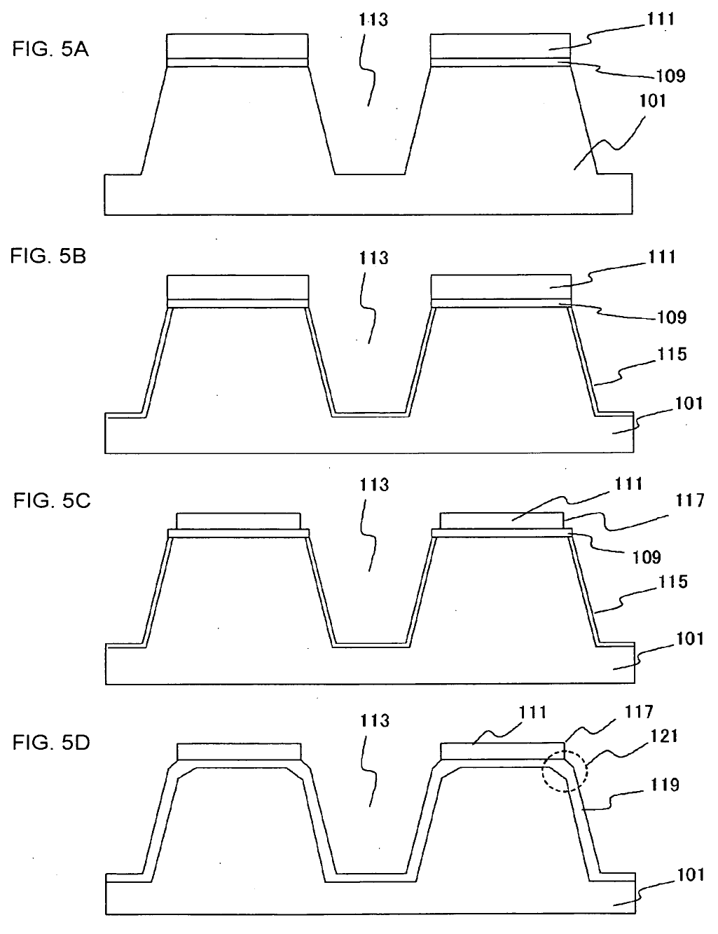

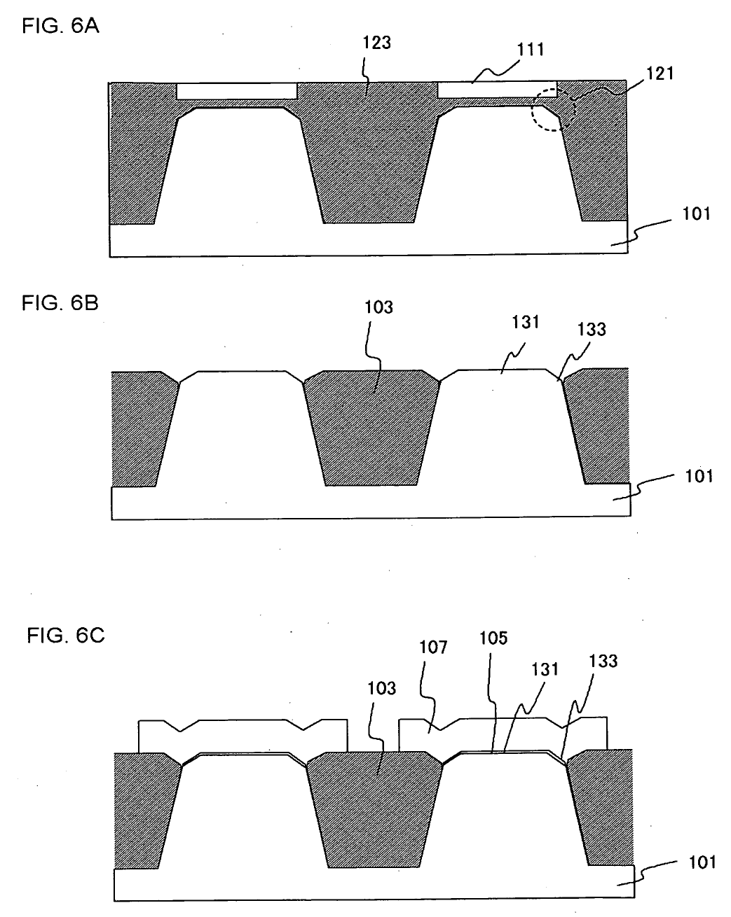

Next, there will be described a process for manufacturing the MOS field-effect transistor 100 shown in FIGS. 1 to 3. FIGS. 5A to 5D and 6A to 6C are cross-sectional views schematically showing a process for manufacturing the MOS field-effect transistor 100 shown in FIGS. 1 to 3.

First, an SiO₂ film 109 and an SiN film 111 are sequentially formed on the (100) plane as the principal surface of the single-crystal silicon substrate 101. A thickness of the SiO₂ film 109 is, for example, about 10 nm, and a thickness of the SiN film 111 is, for example, about 100 nm. The SiN film 111 is a mask for forming the inclined surface 133 while ensuring a region to be the upper surface 131 during forming the channel region 108. Then, the SiN film 111 and the trench 113 are sequentially etched off to form the trench 113 as a groove concave while forming an element forming region beside the concave (FIG. 5A).

Next, the whole surface of the single-crystal silicon substrate 101 having the trench 113 is oxidized to deposit an SiO₂ film 115 to, for example, 2 nm on the surface of the single-crystal silicon substrate 101 including the inner surface of the trench 113 (FIG. 5B).

Then, wet etching is conducted to thin the SiN film 111 to, for example, about 85 nm while making the sidewall of the SiN film 111 recede from the trench 113 toward the element forming region to expose a part of the principal surface from the SiN film 111 (FIG. 5C). Here, the sidewall of the SiN film 111 is made to recede substantially in the <010> crystal axis direction of the single-crystal silicon or an axis direction equivalent to the <010> crystal axis direction. Since the sidewall of the SiN film 111 is etched, the end of the SiN film 111 recedes toward the single-crystal silicon substrate 101 rather than toward the end of the SiO₂ film 109, to form a receding part 117. A thickness of the SiN film 111 after the thinning step is adjusted to a level which may allow the film to act as a protecting film in the step of CMP described later with reference to FIG. 6A.

Subsequently, the whole surface of the single-crystal silicon substrate 101 comprising the receding part 117 formed and the single-crystal silicon substrate 101 exposed from the SiN film 111 is oxidized to form an SiO₂ film 119 to, for example 20 nm on the surface of the single-crystal silicon substrate 101 (FIG. 5D). Here, the SiO₂ film 109 and the SiO₂ film 115 is united with the SiO₂ film 119 to be a single film. By forming the receding part 117, an inclined plane 121 is formed on the region where the SiO₂ film 109 is exposed. This step can form the inclined surface 133 oblique to the principal surface in the <010> crystal axis direction or an axis direction equivalent to the <010> crystal axis direction, in single-crystal silicon substrate 101.

In the oxidation in the step shown in FIG. 5D, it is difficult under the generally used conditions to selectively form a crystal plane with a given surface orientation. Therefore, oxidation conditions by which a crystal plane with a given surface orientation of silicon can be selectively obtained are selected. Specifically, oxidation is conducted in the presence of H₂ or H₂O in addition to O₂, as an oxidation method with higher selectivity of crystal plane dependency. More specifically, a steam oxidation method such as ISSG (in situ steam generation) is used under the condition of, for example, 1100° C. Thus, the MOS field-effect transistor 100 where the inclined surface 133 having a given surface orientation is deliberately formed on the single-crystal silicon substrate 101 cannot be formed without such a technique.

Over the whole surface of the single-crystal silicon substrate 101 is deposited by high-density plasma CVD (Chemical Vapor Deposition) an SiO₂ film 123 to be an element isolation region 103 while filling the trench 113 with the SiO₂ film 123. Then, the substrate is heated at about 800° C. for stabilizing film quality of the SiO₂ film 123, so that the SiO₂ film 123 is united with the SiO₂ films 109, 115 and 119. Then, the SiO₂ film 123 formed over the SiN film 111 by CMP is removed by polishing (FIG. 6A).

Next, the exposed parts of the SiO₂ film 123, the SiN film 111 and the SiO₂ film 109 are sequentially removed by wet etching (FIG. 6B). Thus, the element isolation region 103 is formed in the single-crystal silicon substrate 101, and the channel region 108 having the upper surface 131 and the inclined surface 133 is formed.

In FIG. 6B, the end of the element isolation region 103 is inclined. In FIG. 2 and FIGS. 7 and 8 described later, a cross section of the element isolation region 103 can be also as shown in FIG. 6B. Thus, a steep step can be avoided to reduce the amount of overetching during etching the gate electrode 107.

Then, the whole upper surface of the single-crystal silicon substrate 101 is oxidized to form a gate insulating film 105 to, for example, 1.5 nm. Then, a polysilicon gate electrode film is formed to 120 nm as a gate electrode 107 crossing over the channel region 108. The polysilicon gate electrode film is processed into the shape of the gate electrode 107. The gate electrode 107 is formed over the single-crystal silicon substrate 101 in the element forming region including the inclined surface 133 and extends substantially in the <010> crystal axis direction of the single-crystal silicon or an axis direction substantially equivalent to the <010> crystal axis direction (FIG. 6C). After these steps, the MOS field-effect transistor 100 shown in FIGS. 1 to 3 can be provided.

Next, there will be described the effects of the MOS field-effect transistor 100 shown in FIGS. 1 to 3.

In the MOS field-effect transistor 100 shown in FIGS. 1 to 3, a rectangle-forming pattern in the element isolation region 103, that is, two adjacent sides of the channel region 108, extends in the <010> axis direction and the <001> axis direction, in the principal surface of the single-crystal silicon substrate 101. Furthermore, the gate electrode 107 extend in the <010> axis direction. Therefore, a channel length direction connecting the source/drain regions 129 is the <001> axis direction, and the channel region 108 has the upper surface 131 and the inclined surface 133.

By such a configuration, in the MOS field-effect transistor 100, a surface orientation in the inclined surface 133 of the MOS field-effect transistor 100 can be an <ab0> axis direction of the single-crystal silicon or an axis direction equivalent to the <ab0> crystal axis direction, wherein “a” and “b” are independently an integer and may be the same or different. The inclined surface 133 may be a plane inclined from the {100} plane to the {101} plane and thus a plane with higher channel mobility can be selectively formed in the inclined surface 133. Therefore, channel mobility can be improved in relation to a conventional configuration where the upper surface of the single-crystal silicon substrate directly below the gate electrode is a plane substantially parallel to the principal surface of the substrate. In particular, in this embodiment where the MOS field-effect transistor 100 is of P channel type, ON-state current properties can be significantly improved in comparison with an N channel type transistor.

When a sidewall as described in this embodiment is formed in a channel region of a conventional semiconductor device in which a gate electrode extends in a <011> axis direction, the sidewall is a plane inclined from the {100} plane toward the {111} plane. With such an inclination direction, channel mobility cannot be so significantly increased as in inclination from the {100} plane to the {101} plane. Therefore, in a transistor with a small channel width, an ON-state current cannot be effectively increased by increasing channel mobility.

Additionally, in the MOS field-effect transistor 100 shown in FIGS. 1 to 3, the inclined surface 133 is formed in the side of the end of the element isolation region 103 in the channel region 108. Thus, in comparison with a configuration without the inclined surface 133, a channel width can be increased by 1/cos θ folds. Such an effect is significant when an area of the inclined surface 133 is 10% or more of an area of a region separating the source/drain regions 129 in the single-crystal silicon substrate 101 seen from the normal line of the principal surface.

An ON-state current of a field-effect transistor is dependent on a width and mobility of the channel region 108 as described above. In this embodiment, a length of the channel region 108 is increased and the channel region 108 comprises the inclined surface 133 having a given inclination angle θ, so that channel mobility can be significantly increased in comparison with a conventional configuration. Thus, an ON-state current of the MOS field-effect transistor 100 can be reliably increased. Furthermore, in a P channel type of the MOS field-effect transistor 100, as a width of a region for forming the channel region 108 is reduced, an ON-state current per a unit channel width increases. Thus, an ON-state current of the MOS field-effect transistor 100 can be improved while meeting the requirement for size reduction in gate processing.

In the MOS field-effect transistor 100, all of the inclined surfaces 133a to 133d are formed by a single plane. A particular plane with higher mobility can be, therefore, reliably formed, depending on a design of the MOS field-effect transistor 100. Thus, the MOS field-effect transistor 100 has a configuration which can give a structure as designed exhibiting a desired ON-state current. Furthermore, conversely, in the MOS field-effect transistor 100, an ON-state current can be reliably predicted, depending on a plane-index design of the inclined surface 133. Therefore, the MOS field-effect transistor 100 with a given design can be reliably manufactured with higher reproductivity. Such an effect can be significantly obtained when the inclined surface 133 has the (301) plane of single-crystal silicon or a plane equivalent to the (301) plane, or a plane within 5° to the (301) plane or a plane equivalent to the (301) plane.

Although the MOS field-effect transistor 100 shown in FIGS. 1 to 3 has a configuration where the gate electrode 107 extends in the <010> direction, the gate electrode 107 may extend in an axis direction substantially equivalent to the <010> axis direction. Examples of an axis substantially equivalent to the <010> axis direction include the <001> axis, the <100> axis, the <0-10> axis, the <00-1> axis and the <−100> axis.

### Embodiment 2

This embodiment relates to the MOS field-effect transistor 100 described in Embodiment 1 where the inclined surface 133 is curved.

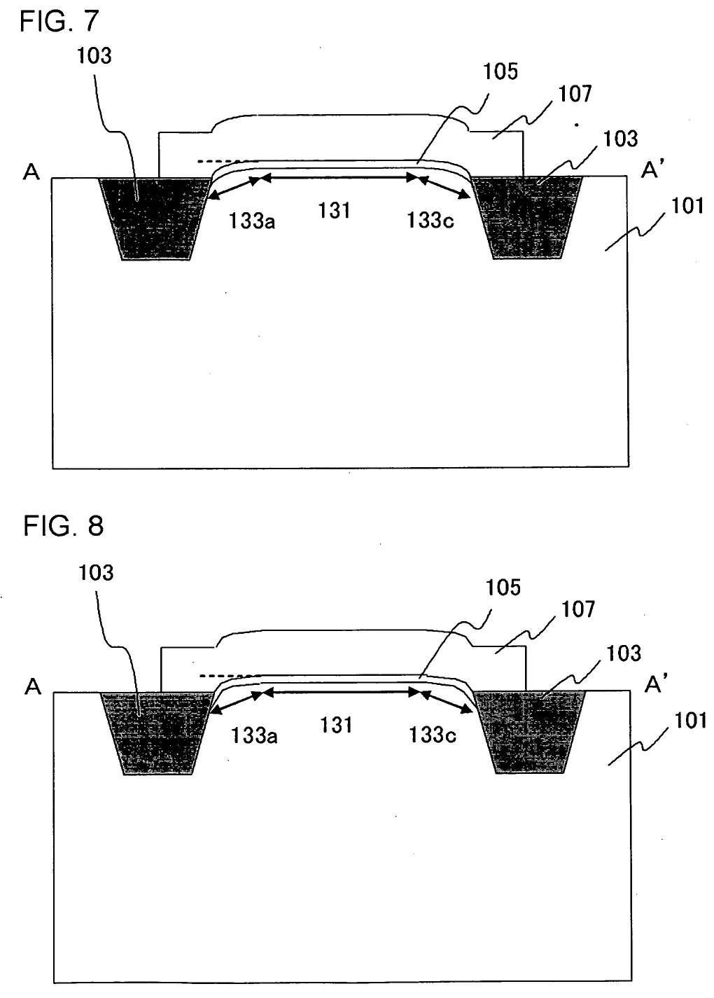

FIG. 7 is a cross-sectional view schematically showing a configuration of a semiconductor device according to this embodiment, from the same direction as FIG. 2. In FIG. 7, both inclined surfaces 133a and 133c are curved.

Since in this configuration, the channel region 108 also has the inclined surface 133 as described in Embodiment 1, a relative area of the inclined surface 133 can be increased to an area of a region separating the source/drain regions 129 in the single-crystal silicon substrate 101 seen from the normal line of the principal surface. The inclined surfaces 133a to 133d are configured such that in the <010> crystal axis direction of the single-crystal silicon or an axis direction equivalent to the <010> crystal axis direction, the surface orientation of the inclined surface 133 varies from the <100> crystal axis direction of the single-crystal silicon to an <ab0> crystal axis direction wherein “a” and “b” are independently an integer, or to a direction equivalent to the <ab0> crystal axis direction. Thus, channel mobility can be increased. Therefore, in the semiconductor device shown in FIG. 7, an ON-state current of the MOS field-effect transistor 100 can be increased.

In the semiconductor device shown in FIG. 7, the inclined surfaces 133a to 133d are curved. It can reliably prevent electric field concentration to a junction between the upper surface 131 and the inclined surface 133, or the end of the element isolation region 103. Thus, the MOS field-effect transistor 100 can be made more reliable.

In this embodiment, the inclined surfaces 133a to 133d may be continuous. Thus, an electric field concentrated point can be eliminated in the channel region, so that stress concentration in the end of the element isolation region 103 can be more reliably alleviated.

### Embodiment 3

This embodiment relates to the MOS field-effect transistor 100 as described in Embodiment 1, where all of the inclined surfaces 133a to 133d are constituted by a plurality of planes.

FIG. 8 is a cross-sectional view schematically showing a configuration of a semiconductor device according to this embodiment, from the same direction as FIG. 2. In FIG. 8, there is shown a configuration where all of the inclined surfaces 133a to 133c are constituted by three planes having a different surface orientation.

By this configuration, a plane having a given inclination angle θ can be formed in the inclined surface 133 as is in Embodiment 1, resulting in increase of a ratio of a region for forming the inclined surface 133 to a width of a region for forming the channel region 108 and improvement of channel mobility. Furthermore, since all of the inclined surfaces 133a to 133d are constituted by the plurality of planes, electric field concentration in the end of the element isolation region 103 can be alleviated. Thus, the MOS field-effect transistor 100 having a higher ON-state current can be manufactured with higher reproductivity, and its reliability as a transistor can be improved.

### Embodiment 4

Although the MOS field-effect transistor 100 is described as a P channel type transistor in the above embodiments, the MOS field-effect transistor 100 may be of N channel type.

When the MOS field-effect transistor 100 is of N channel type, the inclined surface 133 can be formed to effectively increase a channel width, resulting in preventing an ON-state current from being reduced. Thus, ON-state current properties can be improved in, for example, the overall CMOS (Complementary Metal Oxide Semiconductor) device described below.

When the MOS field-effect transistor 100 is of N channel type as in this embodiment, an area of the inclined surface 133 may be 20% or less, preferably 10% or less to an area of a region separating the source/drain regions 129 in the single-crystal silicon substrate 101 seen from the normal line of the principal surface. Thus, reduction in an ON-state current can be prevented.

### Embodiment 5

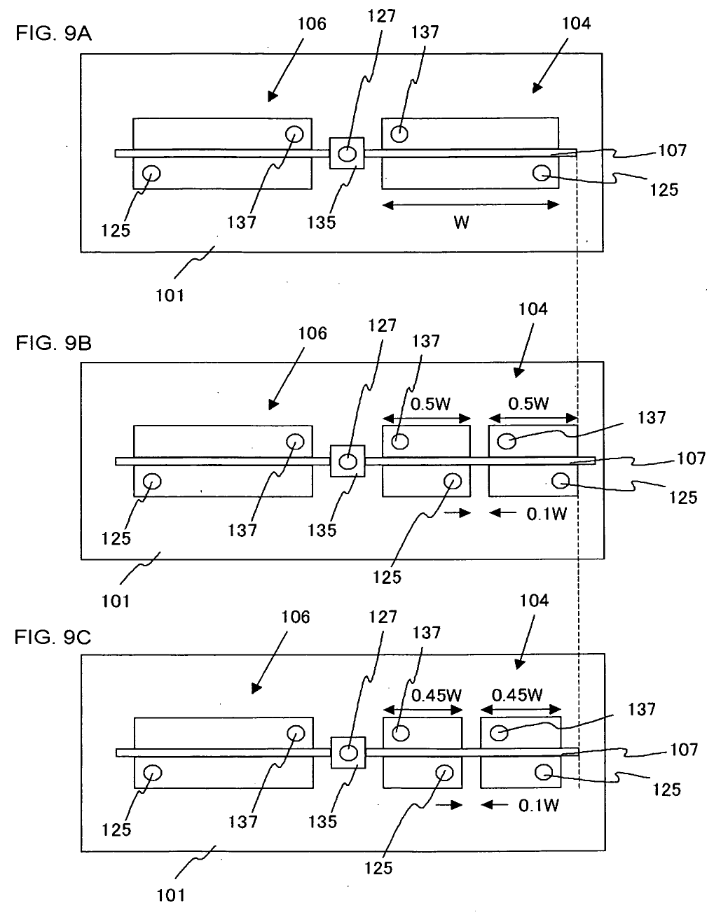

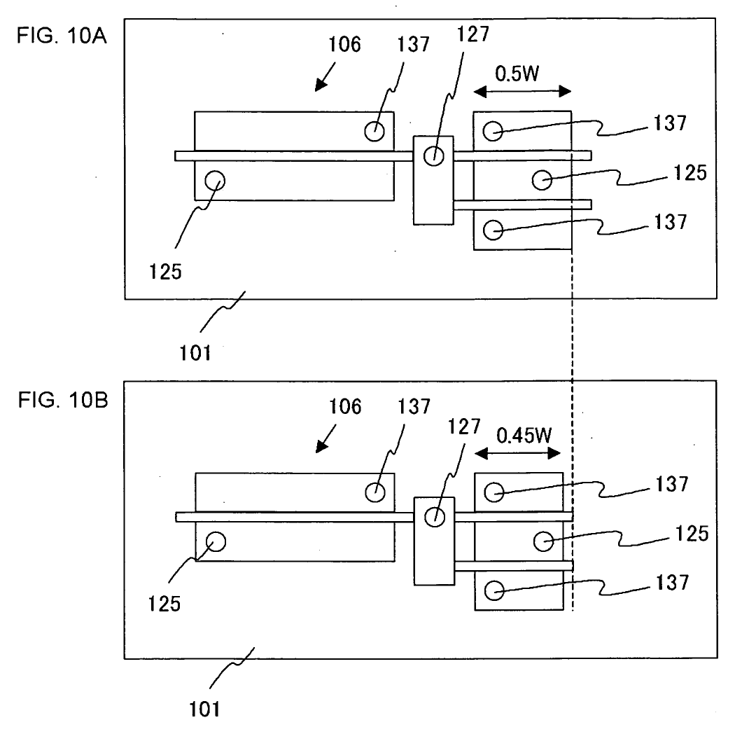

The semiconductor devices described in above embodiments can be applied to a CMOS device. FIGS. 9A to 9C and FIGS. 10A and 10B are plan views schematically showing a configuration of a semiconductor device according to this embodiment.

FIG. 9A shows a configuration of a transistor comprising an N channel MOS field-effect transistor 106 and a P channel MOS field-effect transistor 104. In FIG. 9A and the other drawings related to this embodiment, the N channel MOS field-effect transistor 106 and the P channel MOS field-effect transistor 104 are the MOS type transistors 100 as described in any of the above embodiments. In FIG. 9A and the other drawings related to this embodiment, W is a width of a region for forming the gate electrode 107.

In the semiconductor device shown in FIG. 9A, one gate electrode 107 is formed from the N channel MOS field-effect transistor 106 to the P channel MOS field-effect transistor 104. The gate electrode 107 is connected to the interconnect 135 via a gate connecting plug 127. In the N channel MOS field-effect transistor 106 and the P channel MOS field-effect transistor 104, a source electrode (not shown) is connected to a source connecting plug 125. Furthermore, in the N channel MOS field-effect transistor 106 and the P channel MOS field-effect transistor 104, a drain electrode (not shown) is connected to a drain connecting plug 137.

The semiconductor device shown in FIG. 9A comprises the MOS type transistors 100 as described in any of the above embodiments, as the P channel MOS field-effect transistor 104 and the N channel MOS field-effect transistor 106. Thus, an ON-state current of the P channel MOS field-effect transistor 104 can be increased.

FIGS. 9B and 9C show the configuration of the semiconductor device in FIG. 9A comprising two P channel type MOS field-effect transistors 104 where channel region under the gate electrode 107 is divided into two parts.

FIG. 9B shows a configuration where a width of the gate electrode 107 in one P channel MOS field-effect transistor 104 is a half of that of the N channel MOS field-effect transistor 106. Here, an ON-state current can be increased by 10%.

FIG. 9C shows a configuration where a width of the gate electrode in one P channel MOS field-effect transistor 104 is 0.45 folds of that of the N channel MOS field-effect transistor 106. Here, although an ON-state current is comparable to the configuration in FIG. 9A, an area can be reduced in comparison with the configuration shown in FIG. 9A.

The semiconductor devices shown in FIGS. 9B and 9C have a configuration where a plurality of P channel type MOS field-effect transistors 104 are formed such that the total width of the gate electrode 107 in the P channel type MOS field-effect transistors 104 is substantially equal to the width of the gate electrode 107 in the P channel MOS field-effect transistor 104. Therefore, a proportion of a region for forming the inclined surface 133 can be selectively increased in relation to the width of the region for forming the channel region 108 in the P channel MOS field-effect transistor 104. Thus, reduction in an ON-state current in the N channel MOS field-effect transistor 106 can be prevented while increasing an ON-state current in the P channel MOS field-effect transistor 104. Therefore, the properties of both P channel MOS field-effect transistor 104 and N channel MOS field-effect transistor 106 can be improved in the CMOS device.

FIGS. 10A and 10B show the configuration of the semiconductor device shown in FIG. 9A, wherein there are two P channel type MOS field-effect transistors 104 by dividing the gate electrode 107 into two parts and the two P channel type MOS field-effect transistors 104 share a source connecting plug 125.

FIG. 10A shows the configuration in FIG. 9A, where a width of the gate electrode 107 in the P channel MOS field-effect transistor 104 is a half of that of the N channel MOS field-effect transistor 106. Here, an ON-state current can be increased by 10%.

FIG. 10B shows the configuration in FIG. 9A, where a width of the gate electrode 107 in the P channel MOS field-effect transistor 104 is 0.45 folds of that of the N channel MOS field-effect transistor 106. Here, an area can be reduced in comparison with the configuration shown in FIG. 10A.

Since the number of the source connecting plugs 125 can be reduced in the semiconductor devices shown in FIGS. 10A and 10B, freedom in designing an interconnect can be improved.

Although FIGS. 10A and 10B show the configuration where the two P channel type MOS field-effect transistors 104 share the source connecting plug 125, they may share the drain connecting plug 137.

This effect may be significant when a proportion of the region for forming the inclined surface 133 is 10% or more in relation to a width of the region for forming the channel region 108 in the P channel MOS field-effect transistor 104 while a proportion of the region for forming the inclined surface 133 is less than 10% in relation to a width of the region for forming the channel region 108 in the N channel MOS field-effect transistor 106.

Although the embodiments of this invention have been described with reference to the accompanied drawings, these are only illustrative and various configurations other than the aboves can be employed.

For example, in the above embodiments, the inclined surface 133 in the MOS field-effect transistor 100 may be constituted by a combination of a curved and a flat surfaces.

### EXAMPLE

This example relates to the MOS field-effect transistor 100 described in Embodiment 1 (FIG. 1). An inclination angle was set to 10°, 20° and 30° in each case where the MOS field-effect transistor 100 is a P or N channel type MOSFET. For each inclination angle, a relationship among a gate width WG (that is, a width of a region for forming the channel region 108 seen from the normal line of the principal surface), a width of the region for forming the inclined surface 133(b) and an ON-state current Ion was calculated.

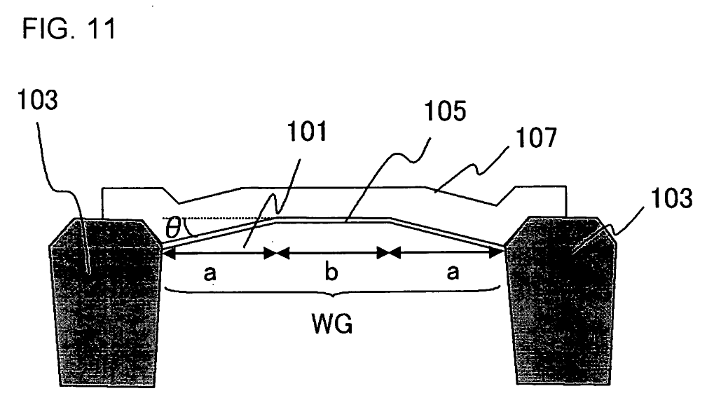

FIG. 11 is a cross-sectional view showing the MOS field-effect transistor 100 in this example, where “a” is a width of the region for forming the inclined surface 133 seen from the normal line of the principal surface; “b” is a width of the region for forming the upper surface 131; “WG” is a gate electrode width; and “θ” is an angle formed between the upper surface 131 and the inclined surface 133, namely, an inclination angle. In FIG. 11,
WG=2a+b;
and
Channel width=b+2a/cos θ.

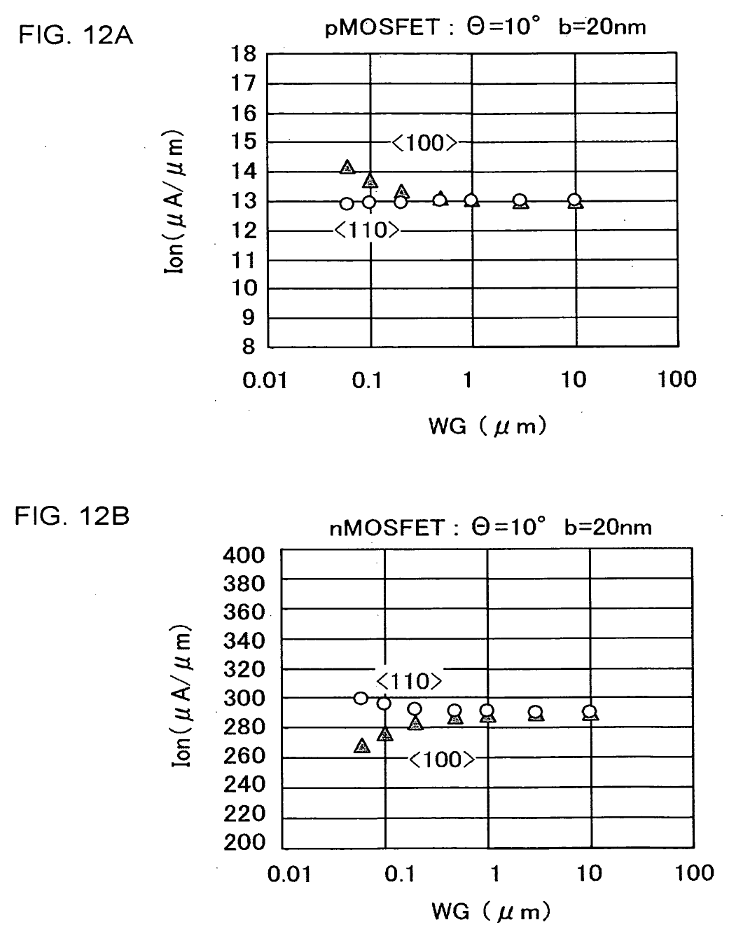

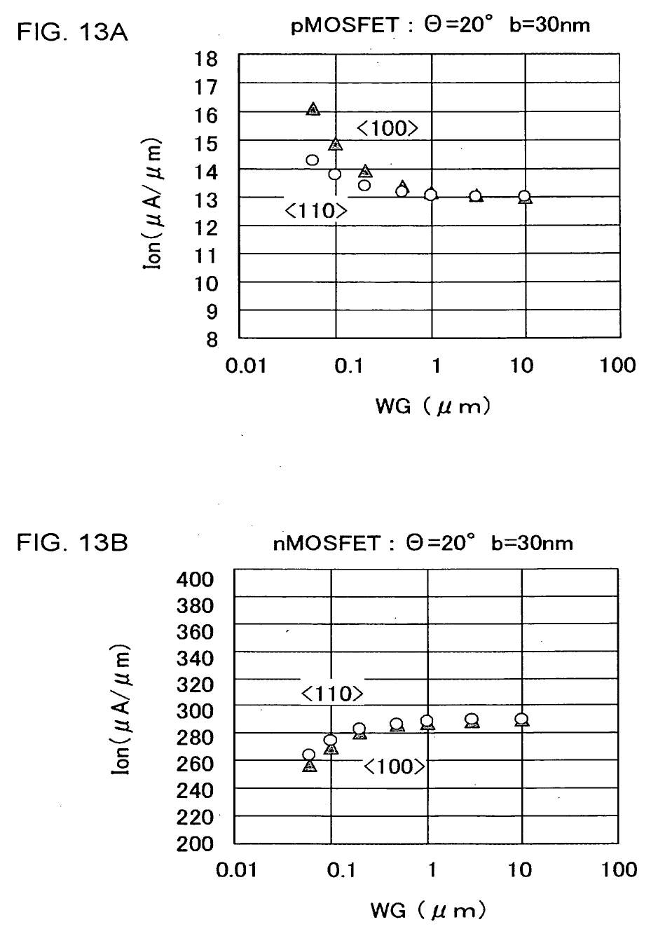

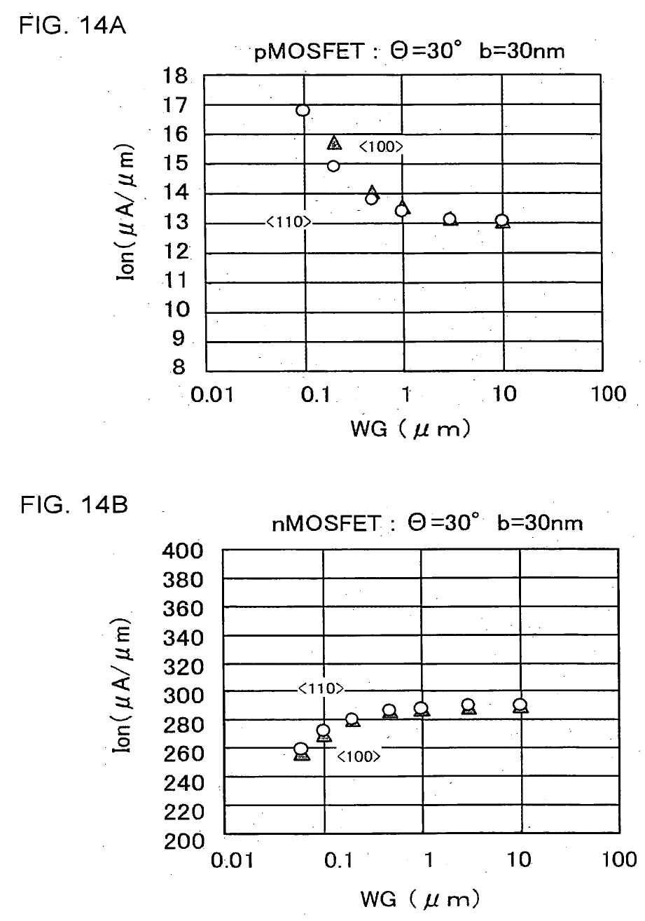

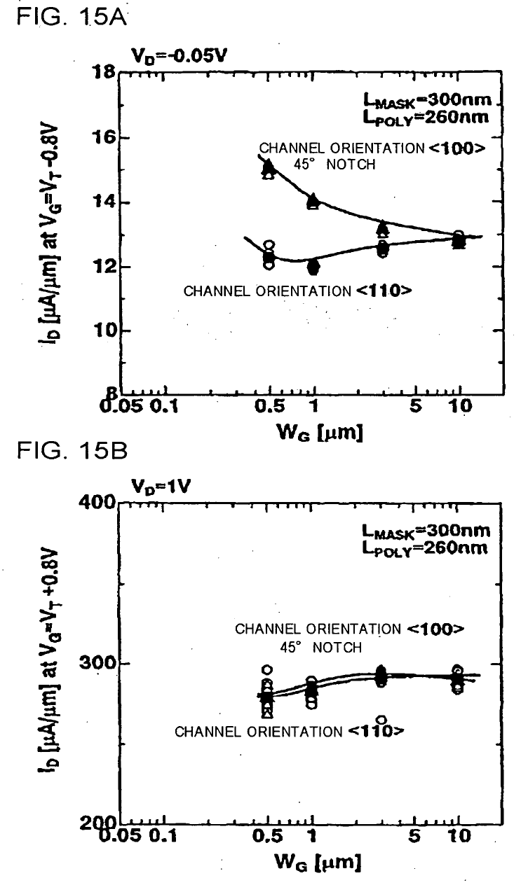

FIGS. 12 to 14 show a relationship between WG and Ion when an inclination angle θ is 10°, 20° or 30°. In FIGS. 12A, 13A and 14A, the MOS field-effect transistor 100 is a P channel type MOSFET while in FIGS. 12B, 13B and 14B, the MOS field-effect transistor 100 is an N channel type MOSFET. In these drawings, <110> and <100> indicate extension directions of the gate electrode 107. Extension of the gate electrode 107 in the <100> direction corresponds to a configuration of the MOS field-effect transistor 100 described in any of the above embodiments, while extension of the gate electrode 107 in the <110> direction corresponds to a configuration in a conventional transistor.

FIGS. 12A, 13A and 14A demonstrate that by forming the gate electrode 107 in the <100> axis direction, a higher Ion can obtained in the P channel type MOSFET than that for the <110> axis direction. Furthermore, FIGS. 12B, 13B and 14B demonstrate that when the gate electrode 107 is formed in the <100> axis direction, Ion reduction in the N channel type MOSFET can be inhibited to a level comparable to the <110> axis direction.

The MOS field-effect transistor 100 described in Embodiment 1 (FIG. 1) was practically manufactured and evaluated as described above, giving the results shown in FIGS. 15A and 15B. FIGS. 15A and 15B show relationship between WG and an ON-state current when the inclined surface 133 is the (30-1) and (301) planes, respectively. FIGS. 15A and 15B demonstrate that Ion reduction in the N channel type MOSFET (FIG. 15B) can be inhibited while improving an ON-state current of the P channel MOS field-effect transistor 104 (FIG. 15A).

It is apparent that the present invention is not limited to the above embodiment, that may be modified and changed without departing from the scope and spirit of the invention.

What is claimed is:

1. A field-effect transistor comprising:
a substrate made of single-crystal silicon having a {100} plane as a principal surface;
a gate electrode on said substrate, which extends substantially in a direction of a <010> crystal axis of said single-crystal silicon or of an axis equivalent to said <010> crystal axis direction; and
source/drain regions on the surface of said substrate in both sides of said gate electrode,
wherein said surface of said substrate directly below said gate electrode has said principal surface and an inclined surface oblique to said principal surface along an extension direction of said gate electrode.

2. The field-effect transistor according to claim 1, further comprising
an element isolation region on said substrate; and
an element region on said substrate defined by said element isolation region,
wherein said gate electrode is formed from said element region to said element isolation region such that it divides said element region; and
wherein said source/drain regions are formed on said surface of said substrate in both sides divided by said gate electrode.

3. The field-effect transistor according to claim 2, wherein said inclined surface is formed near said element isolation region.

4. The field-effect transistor according to claim 1, wherein said inclined surface is constituted by a single crystal plane of said single-crystal silicon.

5. The field-effect transistor according to claim 1, wherein said inclined surface is constituted by a plurality of crystal planes of said single-crystal silicon.

6. The field-effect transistor according to claim 1, wherein said inclined surface comprises a (301) plane of said single-crystal silicon or a plane equivalent to said (301) plane, or a plane having an angle difference within 5° to said (301) plane or said plane equivalent to said (301) plane.

7. The field-effect transistor according to claim 1, wherein said inclined surface is curved and along said <010> crystal axis direction of said single-crystal silicon or said axis direction equivalent to said <010> crystal axis direction, a surface orientation of said inclined surface continuously varies from said <100> crystal axis direction of said single-crystal silicon to an <ab0> crystal axis direction where “a” and “b” are independently an integer or to a direction equivalent to said <ab0> crystal axis direction.

8. The field-effect transistor according to claim 1, wherein an area of said inclined surface is 10% or more of an area of a region separating said source/drain regions in said substrate seen from the normal line of said principal surface.

9. A complementary field-effect transistor comprising an N channel field-effect transistor and a P channel field-effect transistor, wherein said N channel field-effect transistor and said P channel field-effect transistor are said field-effect transistors according to claim 1.

10. The complementary field-effect transistor according to claim 9,
wherein in said P channel field-effect transistor, an area of said inclined surface is 10% or more of an area of a region separating said source/drain regions in said substrate seen from the normal line of said principal surface,
while in said N channel field-effect transistor, an area of said inclined surface is less than 10% of an area of said region separating said source/drain regions in said substrate seen from the normal line direction of said principal surface.

11. The complementary field-effect transistor according to claim 9, further comprising
a plurality of said P channel field-effect transistors divided by an element isolation region and
said single N channel field-effect transistor.

12. A method of manufacturing a field-effect transistor comprising:
depositing a mask on a principal surface of a substrate made of single-crystal silicon having a {100} plane as said principal surface;
sequentially removing said mask and said substrate to form a concave while forming an element forming region beside said concave;
shrinking said sidewall of said mask deposited in said depositing from said concave toward said element forming region to expose a part of said principal surface from said mask;
after said exposing said part of said principal surface from said mask, oxidizing the whole surface of said substrate to form an inclined surface oblique to said principal surface in a <010> crystal axis direction or an axis direction substantially equivalent to said <010> crystal axis direction in said substrate exposed from said mask;
filling said concave with an insulating film to form an element isolation region; and
removing said mask to form a gate electrode extending substantially in said <010> crystal axis direction of said single-crystal silicon or in the axis direction substantially equivalent to said <010> crystal axis direction on said substrate in said element forming region comprising said inclined surface.
